(19) United States
(12) Patent Application Publication
(10) Pub. No.: US 2024/0120563 A1
(43) Pub. Date: Apr. 11, 2024

(54) SENSING BLOCK AND BATTERY MODULE ASSEMBLY INCLUDING THE SAME

(71) Applicants: HYUNDAI MOTOR COMPANY, Seoul (KR); KIA CORPORATION, Seoul (KR); VALEO KAPEC CO., LTD., Daegu (KR)

(72) Inventors: Hyunchang Kang, Seoul (KR); Bum Jin Kim, Hwaseong-si (KR); Kyubin Chung, Seoul (KR); Seoha Kang, Hanam-si (KR); Ji Woong Han, Daegu (KR); Wan Choi, Daegu (KR); Houk Park, Daegu (KR); Jae Eun Kim, Daegu (KR)

(73) Assignees: HYUNDAI MOTOR COMPANY, Seoul (KR); KIA CORPORATION, Seoul (KR); VALEO KAPEC CO., LTD., Daegu (KR)

(21) Appl. No.: 18/225,965

(22) Filed: Jul. 25, 2023

(30) Foreign Application Priority Data
Oct. 6, 2022 (KR) 10-2022-0127983

(51) Int. Cl. H01M 10/48; G01R 31/385; H01M 10/058

(52) U.S. Cl. CPC H01M 10/482; G01R 31/385; H01M 10/058; H01M 10/0525

(57) ABSTRACT

A sensing block includes a block body having a plurality of slots through which electrode leads of battery cells pass, a plurality of sensing terminals installed between the plurality of slots on a front surface of the block body, a circuit board installed on the front surface of the block body, and a connector installed on the circuit board.

### CROSS-REFERENCE TO RELATED APPLICATION

This application claims the benefit of and priority under 35 U.S.C. § 119 to Korean Patent Application No. 10-2022-0127983, filed on Oct. 6, 2022, in the Korean Intellectual Property Office, the disclosure of which is incorporated herein by reference in its entirety.

### BACKGROUND

### 1. Field

The present disclosure relates to a sensing block and a battery module assembly including the same.

### 2. Description of the Related Art

As technology development and demand for mobile devices increase, demand for secondary batteries as an energy source is rapidly increasing as well. Nickel cadmium batteries or hydrogen ion batteries have been generally used as conventional secondary batteries. Recently, lithium ion batteries and lithium polymer batteries having high energy densities have been widely used.

A lithium secondary battery with high output and capacity compared to weight using lithium transition metal oxide, lithium composite oxide, etc., as a cathode active material is greatly in the spotlight. In general, a lithium secondary battery has a structure in which an electrode assembly of a positive electrode/separator/negative electrode is embedded in a sealed container together with an electrolyte.

Lithium secondary batteries consist of a positive electrode, a negative electrode, a separator interposed therebetween, and an electrolyte, and are classified into a lithium ion battery (LIB), a polymer lithium ion battery (PLIB), and the like, depending on which positive and negative active materials are used. In general, the electrodes of these lithium secondary batteries are formed by coating a positive electrode or negative electrode active material on a current collector such as an aluminum or copper sheet, mesh, film, and foil, and then drying the electrode.

In a secondary battery module, a slave type battery management system (BMS) that provides data on voltage and/or temperature of individual cells is used on the module side. Further, for example in the case of a secondary battery pack for automobiles, a BMS in the form of a master is provided at an upper stage such as a power conversion system (PCS) or a battery management module (BMM) to comprehensively manage functions of the entire secondary battery pack.

In prior art systems, because there are various secondary battery modules, and structures and locations of a cartridge constituting the module and a bus bar for sensing are different, an efficient connection work is typically difficult and the welding quality of sensing structures tends to deteriorate. Also, an unnecessary space of the secondary battery module needs to be prepared for welding or the like. Thus, the energy density of the secondary battery module may decrease.

### SUMMARY

An aspect of the present disclosure provides a sensing block having a structure capable of stably welding between an electrode lead of a battery cell and a bus bar.

Another aspect of the present disclosure provides a battery module assembly with a simplified assembly process.

Additional aspects of the present disclosure are set forth in part in the description which follows and, in part, should be apparent from the description or may be learned by practice of the present disclosure.

In accordance with an aspect of the present disclosure, a sensing block configured to sense states of battery cells of a battery module assembly is provided. The sensing block includes a block body having a plurality of slots through which electrode leads of the battery cells pass. The sensing block also includes a plurality of sensing terminals installed between the plurality of slots on a front surface of the block body. The sensing block additionally includes a circuit board installed on the front surface of the block body. The sensing block further includes a connector installed on the circuit board.

The sensing block may further include high-voltage bus bars installed on opposite side edges of the block body. The sensing block may also include an insert bolt electrically connected to the high-voltage bus bar to draw a voltage.

The block body may be manufactured by an insert injection method after the insert bolt is mounted in a mold.

A fixing part for fixing the high-voltage bus bar may be formed on a side of the block body. The fixing part may be configured to be compressed by a thermal fusion method after penetrating the high-voltage bus bar.

A hole and a groove may be formed on lower and upper ends of the high-voltage bus bar, respectively. The fixing part may include a lower fixing part penetrating the hole and an upper fixing part fitted into the groove.

A fixing part for fixing the sensing terminal may be formed on the front surface of the block body. The fixing part may be configured to be compressed by a thermal fusion method after penetrating the sensing terminal.

An upper hole and a lower hole may be formed, respectively, on an upper and a lower end of the sensing terminal. The fixing part may include an upper fixing part and a lower fixing part penetrating, respectively, the upper hole and the lower hole.

A plurality of soldering holes may be formed at an upper portion of the circuit board. Lower ends of the plurality of sensing terminals may penetrate the plurality of soldering holes and then may be soldered and fixed.

A fixing part for fixing the circuit board may be formed at a lower portion of the front surface of the block body. The fixing part may be configured to be compressed by a thermal fusion method after penetrating a fixing hole formed on the circuit board.

The fixing hole may be formed at a position out of a conductive line of the circuit board.

In accordance with another aspect of the present disclosure, a battery module assembly includes a plurality of battery cell cartridges stacked and assembled with each other. The battery module assembly also includes a plurality of battery cells seated on the battery cell cartridges, each battery cell comprising a cell body and electrode leads formed on opposite sides of the cell body. The battery module assembly further includes a sensing block installed on sides of the plurality of stacked cell cartridges. The sensing block includes a block body having a plurality of slots through which electrode leads of the battery cells pass. The sensing block also includes a plurality of sensing terminals installed between the plurality of slots on a front surface of the block body. The sensing block additionally includes a circuit board installed on the front surface of the block body. The sensing block further includes a connector installed on the circuit board.

A guiding groove may be formed at an upper end of the battery cell cartridge. A guiding protrusion provided to be fitted into the guiding groove may be formed at an upper end of the block body of the sensing block.

A guiding groove may be formed at a lower end of the battery cell cartridge, A guiding protrusion provided to be fitted into the guiding groove may be formed at a lower end of the block body of the sensing block.

Holes may be formed at a side of the battery cell cartridge. Protrusions provided to be fitted into the holes may be formed on a rear surface of the block body of the sensing block.

The holes may be formed at upper and lower portions of the side of the battery cell cartridge. The protrusions may be formed at upper and lower portions of the rear surface of the sensing block.

A snap-fit part acting as a locking jaw for preventing the sensing block from being separated from battery cell cartridge may be formed at an upper portion of the block body of the sensing block.

The electrode lead of the battery cell disposed adjacent to opposite sides of the sensing terminal may be folded to come into contact with the sensing terminal and then electrically connected to the sensing terminal through three-sided laser welding.

The sensing block may further include a high-voltage bus bar installed on opposite side edges of the block body. The electrode lead of the battery cell disposed adjacent to the high-voltage bus bar may be electrically connected to the high-voltage bus bar through two-sided laser welding.

### BRIEF DESCRIPTION OF THE DRAWINGS

These and/or other aspects of the present disclosure should become apparent and more readily appreciated from the following description of the embodiments, taken in conjunction with the accompanying drawings, in which:

FIG. 1 is a perspective view illustrating a state in which sensing blocks are separated from stacked battery cell cartridges in a battery module assembly according to an embodiment of the present disclosure;

FIG. 2 is an enlarged view of a portion A shown in FIG. 1;

FIG. 3 is an enlarged view of a portion B shown in FIG. 1;

FIG. 4 is a perspective view illustrating a portion corresponding to the sensing block in the battery module assembly according to an embodiment of the present disclosure;

FIG. 5 is a top view illustrating a series connection structure of battery cells in the battery module assembly illustrated in FIG. 4;

FIG. 6 is a perspective view for explaining a process of manufacturing a block body in the sensing block according to an embodiment of the present disclosure;

FIGS. 7A and 7B are perspective views for explaining a process of coupling a high-voltage bus bar to the block body in the sensing block illustrated in FIG. 6;

FIG. 8 is a perspective view for explaining a process of coupling sensing terminals to the block body in the sensing block illustrated in FIG. 6;

FIG. 9 is a perspective view illustrating a state in which the sensing terminals are coupled to the block body illustrated in FIG. 8;

FIG. 10 is a perspective view illustrating a state in which a circuit board is separated from the sensing block illustrated in FIG. 6; and

FIG. 11 is an enlarged view of a portion C shown in FIG. 4.

### DETAILED DESCRIPTION

Hereinafter, embodiments of the present disclosure are described in detail with reference to the accompanying drawings. The embodiments described below are provided by way of example to enable those having ordinary skill in the art to fully understand the spirit of the inventive concepts. The present disclosure is not limited to the embodiments described below, but may be embodied in other forms. In order to clearly explain the inventive concepts, parts or components not related to the description may be omitted from the accompanying drawings. Further, sizes of components illustrated in the accompanying drawings may be exaggerated for convenience.

When a component, device, element, or the like of the present disclosure is described as having a purpose or performing an operation, function, or the like, the component, device, or element should be considered herein as being “configured to” meet that purpose or perform that operation or function.

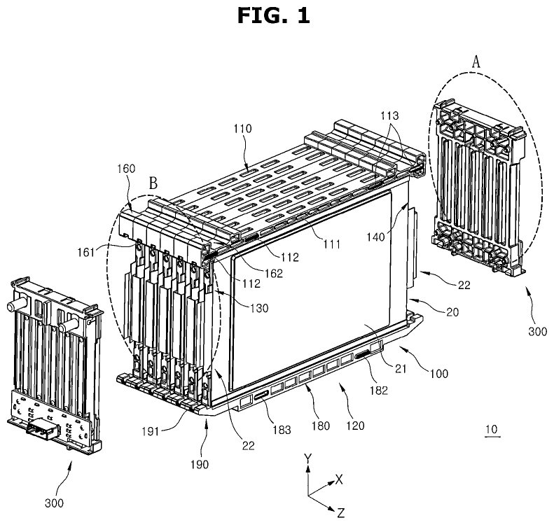

In coordinate axes illustrated in FIGS. 1-11, an X axis represents a ‘horizontal direction’, a Y axis represents a ‘vertical direction, and a Z axis represents a ‘stacking direction’.

FIG. 1 is a perspective view illustrating a state in which sensing blocks are separated from stacked battery cell cartridges in a battery module assembly according to an embodiment of the present disclosure.

A battery module assembly 10 may include a plurality of battery cell cartridges 100 stacked and assembled with each other and a plurality of battery cells seated on the battery cell cartridges 100. The battery cell 20 may include a cell body 21 and electrode leads 22 formed on opposite sides of the cell body 21. The battery module assembly 10 may also include a sensing block 300 installed on sides of the plurality of stacked cell cartridges 100.

The battery cell cartridge 100 may be configured in the form of a frame for seating the battery cells 20 thereon. The battery cell cartridge 100 may be made of a synthetic resin material, for example. The battery cell 20 may include the cell body 21 and the electrode leads (e.g., cell tabs) 22. Two of the electrode leads 22 may be provided on opposite sides of the cell body 21 to indicate positive and negative poles.

The battery cell cartridge 100 may include a first frame 110 extending in a horizontal direction, a second frame 120 spaced apart from the first frame 110 at a predetermined interval and extending in the horizontal direction, a third frame 130 extending in a vertical direction to connect first ends of the first frame 110 and the second frame 120, and a fourth frame 140 extending in the vertical direction to connect second ends of the first frame 110 and the second frame 120.

A plurality of the battery cell cartridges 100 may be provided. Further, a structure for coupling the battery cell cartridges 100 to each other may be provided. An embossed part 112 having a protruding shape and a recessed part 113 having a concave shape may be formed on a surface 111 of the first frame 110. Therefore, the first frame 110 positioned on a front side and the second frame 120 positioned on a rear side with respect to the two adjacent battery cell cartridges 100 may have a structure of being coupled to each other.

A sensing block coupler 160 having a guiding groove 161 may be formed at each of opposite ends of the first frame 110. In addition, a seating protrusion 170 protruding upward may be formed on the first frame 110 to form a recessed part 162 at a predetermined distance from the two sensing block couplers 160.

A lower support 180 extending in the horizontal direction may be formed at a lower end of the second frame 120. An embossed part 182 having a protruding shape and a recessed part 183 having a concave shape may be formed on a surface 181 of the lower support 180. Therefore, the lower support 180 positioned on the front side and the lower support 180 positioned on the rear side with respect to the two adjacent battery cell cartridges 100 may have a structure configured to be coupled to each other.

Two battery cells 20 may be disposed between the two adjacent battery cell cartridges 100. Because the two battery cells 20 are disposed between the two adjacent battery cell cartridges 100, the two battery cells 20 may be seated on opposite sides of one battery cell cartridge 100. When the plurality of battery cell cartridges 100 includes N battery cell cartridges, the battery cells 20 may include 2N battery cells.

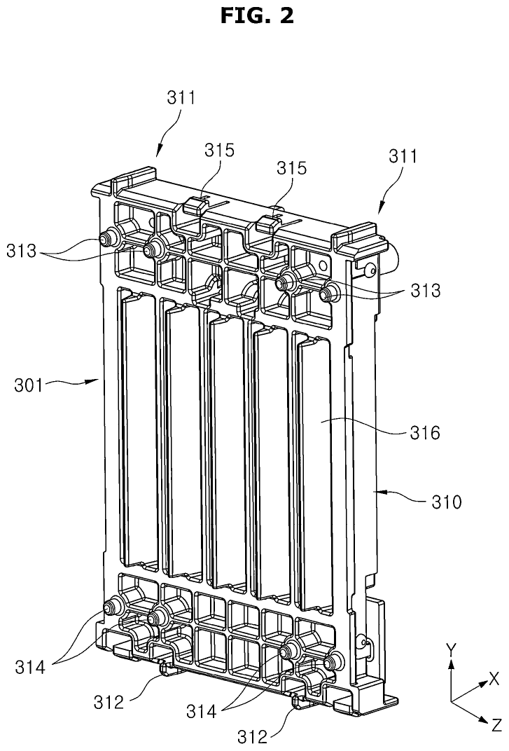

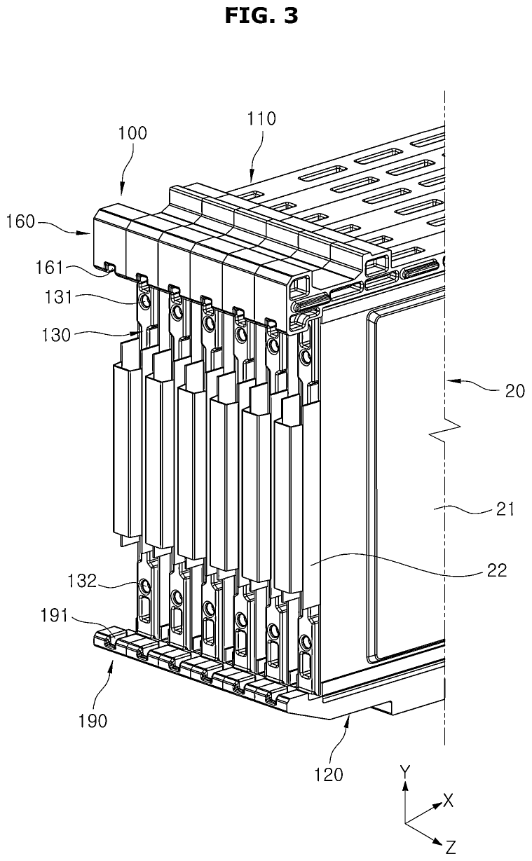

FIG. 2 is an enlarged view of a portion A shown in FIG. 1. FIG. 3 is an enlarged view of a portion B shown in FIG. 1. FIG. 2 illustrates a rear surface 301 of a block body 310 of the sensing block 300.

FIG. 3 illustrates a state in which the electrode leads 22 are folded before the sensing block 300 is installed on the electrode leads 22. Thus, FIG. 3 illustrates a state in which the sensing block 300 is excluded. For example, the sensing block 300 may be assembled to sides of the finally stacked battery cells 20. FIG. 3, however, illustrates a state before the sensing block 300 is assembled.

The two sensing blocks 300 may be provided to be respectively installed on opposite sides of the plurality of stacked battery cell cartridges 100. A separation guide part 316 provided to prevent contact between the two adjacent electrode leads 22 may be formed on the rear surface 301 of the block body 310.

Guiding grooves 161 and 191 may be formed at upper and lower ends of the battery cell cartridge 100. Guiding protrusions 311 and 312 provided to be fitted into the guiding grooves 161 and 191 may be formed on the sensing block 300, The guiding protrusion 311 provided at an upper end of the sensing block 300 may be fitted into the guiding groove 161 formed on the first frame 110, and the guiding protrusion 312 provided at a lower end of the sensing block 300 may be fitted into the guiding groove 191 formed on a sensing block coupler 190 of the second frame 120.

Holes 131 and 132 may be formed on a side of the battery cell cartridge 100, i.e., the third frame 130 and the fourth frame 140, Protrusions 313 and 314 provided to be fitted into the holes 131 and 132 may be formed on the rear surface 301 of the sensing block 300. The holes 131 and 132 may be formed at upper and lower portions of the side of the battery cell cartridge 100, respectively, and the protrusions 313 and 314 may be formed at upper and lower portions of the rear surface 301 of the sensing block 300, respectively.

A snap-fit part 315 acting as a locking jaw for preventing the sensing block 300 from being separated from the first frame 110 may be formed at an upper portion of the sensing block 300. The snap-fit part 315 may act as a locking jaw after penetrating a lower surface of the sensing block coupler 160 to prevent separation of the sensing block 300.

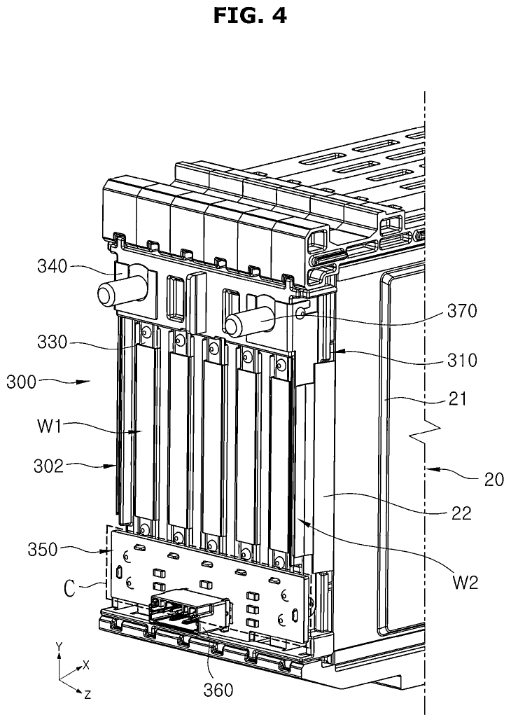

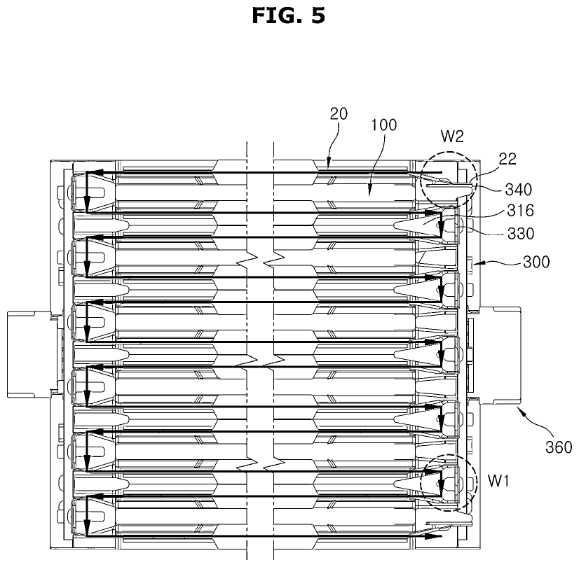

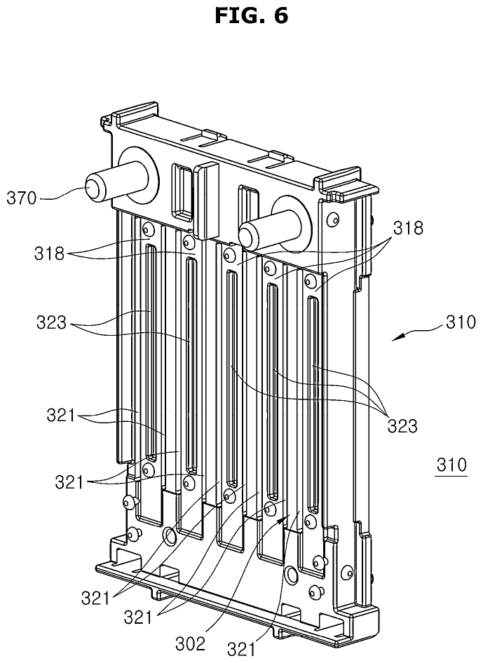

FIG. 4 is a perspective view illustrating a portion corresponding to the sensing block in the battery module assembly according to an embodiment of the present disclosure. FIG. 5 is a top view illustrating a series connection structure of battery cells in the battery module assembly illustrated in FIG. 4. FIG. 6 is a perspective view for explaining a process of manufacturing a block body in the sensing block according to an embodiment of the present disclosure.

The sensing block 300 may be configured to sense a state of the battery cell 20. The sensing block 300 may include the block body 310 having a plurality of slots 321 for passing the electrode leads 22 of the battery cells 20. The sensing block 300 may also include a plurality of sensing terminals 330 installed between the plurality of slots 321 on a front surface 302 of the block body 310. The sensing block 300 may additionally include a high-voltage bus bar 340 installed on opposite side edges of the block body 310. The sensing block 300 may further include a circuit board 350 installed on the front surface 302 of the block body 310 and a connector 360 installed on the circuit board 350. The sensing block 300 may further still include an insert bolt 370 electrically connected to the high-voltage bus bar 340 to draw a voltage.

A discharge space 323 for discharging welding gas during welding may be formed between a pair of slots 321. The sensing terminal 330 may be disposed in the discharge space 323. The electrode leads 22 passed through the plurality of slots 321 may be overlapped on the sensing terminal 330 so that three-sided welding may be achieved.

In the battery module assembly 10, the sensing block 300 on the high-voltage bus bar 340 side of the stacked battery cells 20 has five sensing terminals 330 as illustrated in FIG. 6. On the other hand, the opposite side of the sensing block 300 without the high-voltage bus bar 340 has six sensing terminals 330 as shown on the left side of FIG. 5.

The connector 360 may be configured to transmit a signal sensed by the sensing block 300 to the outside.

Referring to a portion marked as ‘W1’ in FIGS. 4 and 5, the electrode lead 22 of the battery cell 20 disposed adjacent to opposite sides of the sensing terminal 330 may first pass through the slot 321 of the block body 310 and then be folded to come into contact with the sensing terminal 330. The electrode 22 of the battery cell 20 disposed adjacent to opposite sides of the sensing terminal 330 may then be electrically connected to the sensing terminal 330 through three-sided laser welding. Referring to a portion marked as ‘W2’ in FIGS. 4 and 5, the electrode lead 22 of the battery cell 20 disposed adjacent to the high-voltage bus bar 340 may be electrically connected to the high-voltage bus bar 340 through two-sided laser welding.

Referring to FIG. 5, a total of twelve battery cells 20 may be connected in series from the positive electrode to the negative electrode in the direction of arrows through the above-described three-sided welding and two-sided welding.

Referring to FIG. 6, a process of manufacturing the block body 310 of the sensing block 300, according to an embodiment, is explained. The block body 300 may be manufactured by an insert injection method after the insert bolt 370 is mounted in a mold (not shown). It may be seen that the sensing terminals 330 may be fixed to installation regions 318 positioned on opposite sides of the separation guide part 316 on the front surface 302, and the slots 321 are formed on opposite sides of the corresponding separation guide part 316.

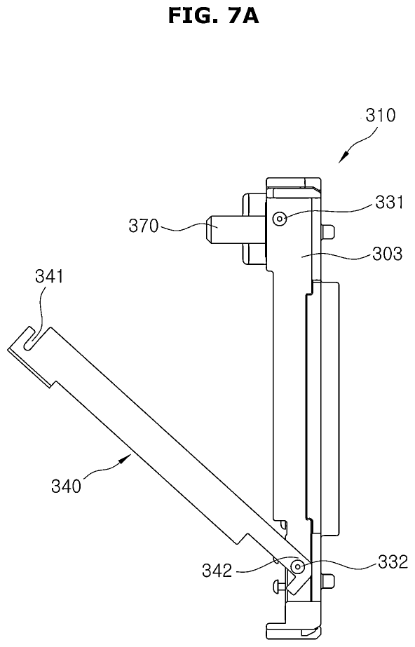

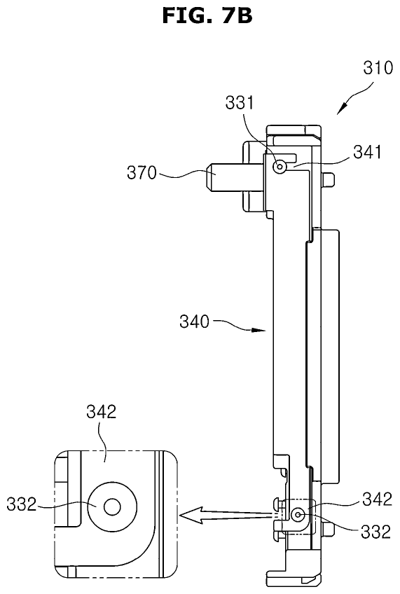

FIGS. 7A and 7B are perspective views for explaining a process of coupling a high-voltage bus bar to the block body in the sensing block illustrated in FIG. 6. A process of fixing the high-voltage bus bar 340 to the block body 310 is described below with reference to FIGS. 7A and 7B.

Fixing parts 331 and 332 for fixing the high-voltage bus bar 340 are formed on a side of the block body 310. The fixing parts 331 and 332 may be configured to be compressed by a thermal fusion method after penetrating the high-voltage bus bar 340. A hole 342 and a groove 341 are formed on lower and upper ends of the high-voltage bus bar 340, respectively. The fixing parts 331 and 332 may include the lower fixing part 332 penetrating the hole 342 and the upper fixing part 331 fitted into the groove 341, The groove 341 may have a shape.

In order to assemble the high-voltage bus bar 340 to the block body 310, as the lower fixing part 332 first passes through the hole 342 of the high-voltage bus bar 340 and then the high-voltage bus bar 340 rotates around the lower fixing part 332 as a rotation axis, the upper fixing part 331 may be fitted into the groove 341.

Because a diameter of the lower fixing part 332 is smaller than a diameter of the hole 342 before the lower fixing part 332 is thermally fused, the lower fixing part 332 may pass through the hole 342. Also, because an end of the lower fixing part 332 is melted and compressed after thermally fused, the lower fixing part 332 may cover the hole 342. This action may be applied to the upper fixing part 331 in the same way,

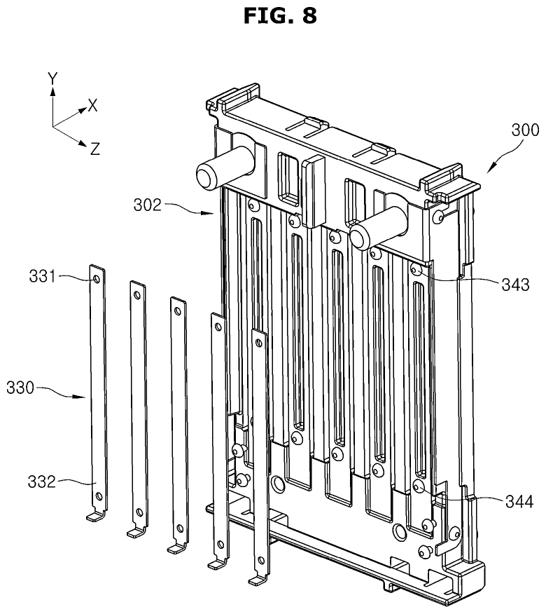

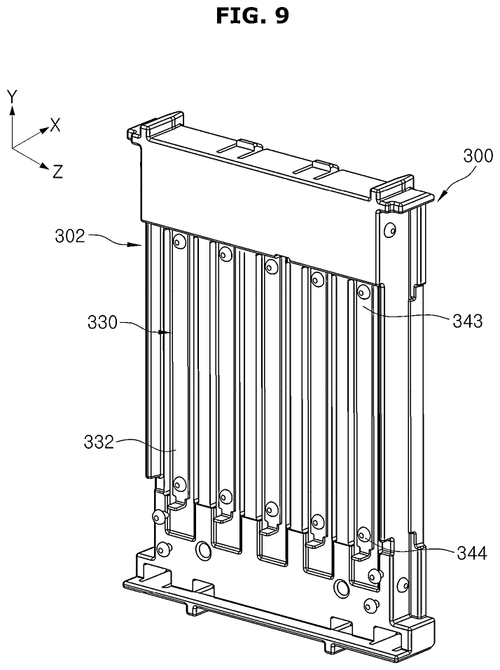

FIG. 8 is a perspective view for explaining a process of coupling sensing terminals to the block body in the sensing block illustrated in FIG. 6. FIG. 9 is a perspective view illustrating a state in which the sensing terminals are coupled to the block body illustrated in FIG. 8. A process of fixing the sensing terminals 330 to the block body 310 is described below with reference to FIGS. 8 and 9.

Fixing parts 343 and 344 for fixing the sensing terminals 330 are formed on a front surface of the block body 310. The fixing parts 343 and 344 may be configured to be compressed by the thermal fusion method after penetrating the sensing terminals 330. An upper hole 333 and a lower hole 334 are formed on upper and lower ends of the sensing terminal 330, respectively. The fixing parts 343 and 344 may include the upper fixing part 343 and the lower fixing part 344 penetrating the upper hole 333 and the lower hole 334, respectively.

Unlike the high-voltage bus bar 340, the upper hole 333 and the lower hole 334 of the sensing terminal 330 may pass through, respectively, the upper fixing part 343 and the lower fixing part 344 concurrently. Next, as the upper fixing part 343 and the lower fixing part 344 are melted and compressed, the sensing terminal 330 may be fixed to the block body 310.

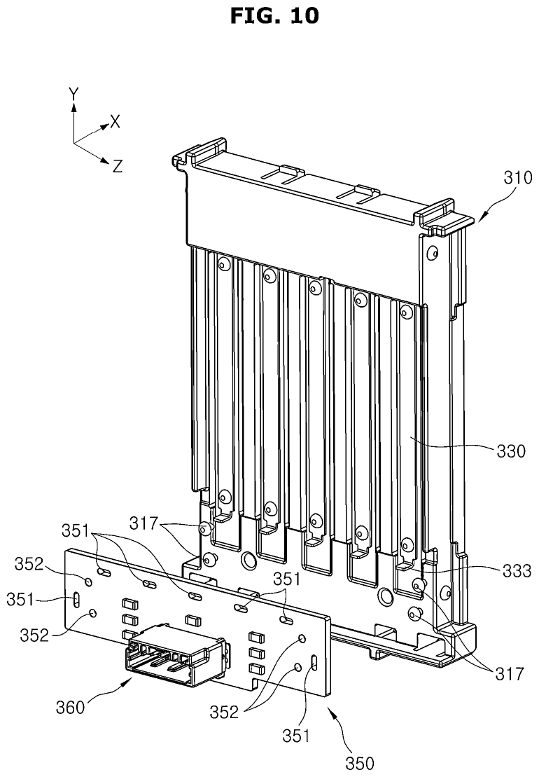

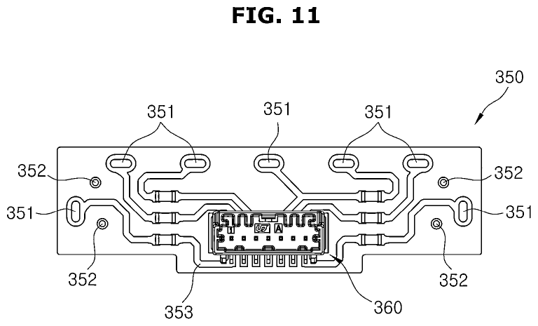

FIG. 10 is a perspective view illustrating a state in which a circuit board is separated from the sensing block illustrated in FIG. 6. FIG. 11 is an enlarged view of a portion C shown in FIG. 4. A process of fixing the circuit board 350 to the block body 310 is described below with reference to FIGS. 10 and 11.

A plurality of soldering holes 351 is formed at an upper portion of the circuit board 350. Lower ends 335 of the plurality of sensing terminals 330 may penetrate the plurality of soldering holes 351, respectively, and then be soldered and fixed. The circuit board 350 and the sensing terminals 330 may thus be electrically connected.

FIG. 10 illustrates five sensing terminals 330, and thus five soldering holes 351 may be provided. On the other hand, as described above, six sensing terminals 330 may be provided on the side of the sensing block 300 to which the high-voltage bus bar 340 is not mounted, and thus six soldering holes 351 may also be provided.

Fixing parts 317 for fixing the circuit board 350 are formed at a lower portion of the front surface 302 of the block body 310. The fixing part 317 may be configured to be compressed by the thermal fusion method after penetrating a fixing hole 352 formed on the circuit board 350. The fixing hole 352 may be formed at a position out of a conductive line 353 of the circuit board 350 based on a stacking direction.

In a sensing block according to an embodiment of the present disclosure, sensing terminals and a high-voltage bus bars are pre-fixed to the block body, coupled to the battery module assembly, and then welded to the electrode leads, so that a stable welding coupling may be achieved between the electrode lead of the battery cell, the sensing terminal, and the high-voltage bus bar. In addition, as the circuit board (e.g., a printed circuit board (PCB)) is fixed to the sensing block, complex wire connections may be removed, thereby simplifying the assembly process.

As should be apparent from the above, a sensing block according to an embodiment of the present disclosure allows electrode leads of a battery cell to be folded from opposite sides with respect to a sensing terminal, so that three-sided welding can be stably achieved.

In addition, a sensing block according to an embodiment of the present disclosure allows the electrode lead of an outermost battery cell to be welded to a high-voltage bus bar, so that double-sided welding can be stably achieved.

A battery module assembly according to an embodiment of the present disclosure allows a circuit board to be fixed to the sensing block, so that complicated wire connections can be removed, thereby simplifying the assembly process.

Although several embodiments of the present disclosure have been described herein with reference to the accompanying drawings, it should be appreciated by those having ordinary skill in the art that various modifications may be made in these embodiments without departing from the principles and spirit of the present disclosure. The scope of the present disclosure is defined in the appended claims and their equivalents.

What is claimed is:

1. A sensing block configured to sense states of battery cells of a battery module assembly, the sensing block comprising:
a block body having a plurality of slots through which electrode leads of the battery cells pass;
a plurality of sensing terminals installed between the plurality of slots on a front surface of the block body;
a circuit board installed on the front surface of the block body; and
a connector installed on the circuit board.

2. The sensing block according to claim 1, further comprising:
respective high-voltage bus bars installed on opposite side edges of the block body; and
an insert bolt electrically connected to a high-voltage bus bar, of the respective high-voltage bus bars, to draw a voltage.

3. The sensing block according to claim 2, wherein the block body is manufactured by an insert injection method after the insert bolt is mounted in a mold.

4. The sensing block according to claim 2, wherein:
a fixing part for fixing a high-voltage bus bar on a side of the block body is formed on the side of the block body; and
the fixing part is configured to be compressed by a thermal fusion method after penetrating the high-voltage bus bar.

5. The sensing block according to claim 4, wherein:
a hole and a groove are formed on, respectively, a lower and an upper end of the high-voltage bus bar; and
the fixing part comprises a lower fixing part penetrating the hole and an upper fixing part fitted into the groove.

6. The sensing block according to claim 1, wherein:
a fixing part for fixing a sensing terminal, of the plurality of sensing terminals, is formed on the front surface of the block body; and
the fixing part is configured to be compressed by a thermal fusion method after penetrating the sensing terminal.

7. The sensing block according to claim 6, wherein:
an upper hole and a lower hole are formed, respectively, on an upper and a lower end of the sensing terminal; and
the fixing part comprises an upper fixing part and a lower fixing part penetrating, respectively, the upper hole and the lower hole.

8. The sensing block according to claim 1, wherein:
a plurality of soldering holes is formed at an upper portion of the circuit board; and
lower ends of the plurality of sensing terminals penetrate the plurality of soldering holes, respectively, and then are soldered and fixed.

9. The sensing block according to claim 1, wherein:
a fixing part for fixing the circuit board is formed at a lower portion of the front surface of the block body; and
the fixing part is configured to be compressed by a thermal fusion method after penetrating a fixing hole formed on the circuit board.

10. The sensing block according to claim 9, wherein the fixing hole is formed at a position out of a conductive line of the circuit board.

11. A battery module assembly, comprising:
a plurality of battery cell cartridges stacked and assembled with each other;
a plurality of battery cells seated on the battery cell cartridges, each battery cell comprising a cell body and electrode leads formed on opposite sides of the cell body; and
a sensing block installed on sides of the plurality of battery cell cartridges, wherein the sensing block includes
a block body having a plurality of slots through which electrode leads of the battery cells pass,
a plurality of sensing terminals installed between the plurality of slots on a front surface of the block body,
a circuit board installed on the front surface of the block body, and
a connector installed on the circuit board.

12. The battery module assembly according to claim 11, wherein:
a guiding groove is formed at an upper end of a battery cell cartridge of the plurality of battery cell cartridges; and
a guiding protrusion provided to be fitted into the guiding groove is formed at an upper end of the block body of the sensing block.

13. The battery module assembly according to claim 11, wherein:
a guiding groove is formed at a lower end of a battery cell cartridge of the plurality of battery cell cartridges; and
a guiding protrusion provided to be fitted into the guiding groove is formed at a lower end of the block body of the sensing block.

14. The battery module assembly according to claim 11, wherein:
holes are formed at a side of a battery cell cartridge of the plurality of battery cell cartridges; and
protrusions provided to be fitted into the holes are formed on a rear surface of the block body of the sensing block.

15. The battery module assembly according to claim 14, wherein:
the holes are formed at an upper and a lower portion of the side of the battery cell cartridge; and
the protrusions are formed at an upper and a lower portion of the rear surface of the sensing block.

16. The battery module assembly according to claim 11, wherein a snap-fit part acting as a locking jaw for preventing the sensing block from being separated from battery cell cartridge is formed at an upper portion of the block body of the sensing block.

17. The battery module assembly according to claim 11, wherein the electrode lead of a battery cell, of the plurality of battery cells, disposed adjacent to opposite sides of a sensing terminal, of the plurality of sensing terminals, is folded to come into contact with the sensing terminal and then electrically connected to the sensing terminal through three-sided laser welding.

18. The battery module assembly according to claim 11, wherein:
the sensing block further comprises a high-voltage bus bar installed on opposite side edges of the block body; and
the electrode lead of a battery cell, of the plurality of battery cells, disposed adjacent to the high-voltage bus bar is electrically connected to the high-voltage bus bar through two-sided laser welding.
